(19) United States
(12) Patent Application Publication
(10) Pub. No.: US 2024/0312803 A1
(43) Pub. Date: Sep. 19, 2024

(54) SUBSTRATE PROCESSING DEVICE

(71) Applicant: Kioxia Corporation, Tokyo (JP)

(72) Inventors: Shusaku MATSUMOTO, Saitama Saitama (JP); Shiguma KATO, Mie Mie (JP); Koichiro KAWANO, Kamakura Kanagawa (JP); Tomoya IWASAKI, Yokkaichi Mie (JP)

(73) Assignee: Kioxia Corporation, Tokyo (JP)

(21) Appl. No.: 18/589,750

(22) Filed: Feb. 28, 2024

(30) Foreign Application Priority Data
Mar. 13, 2023 (JP) 2023-038196

(51) Int. Cl. H01L 21/67; H01L 21/311; H01L 21/687

(52) U.S. Cl. CPC H01L 21/67086; H01L 21/31111; H01L 21/68764; H01L 21/68771

(57) ABSTRACT

A substrate processing device includes a processing tank including a first region, a second region, and a third region, wherein a plurality of substrates are housed in the first region and arranged in a first direction with their faces oriented in an approximately horizontal direction such that a processing of the substrates using a processing solution is carried out, the second region is provided in a vicinity of the first region, and the third region is provided such that the processing solution can move between the first region and the second region; a moving body disposed in the second region of the processing tank and configured to move such that a flow of the processing solution occurs; and a movement mechanism configured to move the moving body.

### CROSS-REFERENCE TO RELATED APPLICATION (S)

This application is based upon and claims the benefit of priority from Japanese Patent Application No. 2023-038196, filed Mar. 13, 2023, the entire contents of which are incorporated herein by reference.

### FIELD

Embodiments described herein relate generally to a substrate processing device.

### BACKGROUND

A process of etching various kinds of film formed on a semiconductor substrate is implemented during a semiconductor device manufacturing process. For example, a three-dimensional stacked non-volatile memory device, in which memory cells are stacked three-dimensionally, is such that when forming a stacked body in which an insulating film and a conductive film are stacked in a periphery of a memory hole, a process of selectively etching a silicon nitride film is implemented with respect to a stacked body in which a silicon oxide film and the silicon nitride film are alternately stacked. For example, a substrate processing device that implements an etching process by a multiple of semiconductor substrates being immersed in a processing tank in which an etching solution is housed is used in the etching process. With this kind of substrate processing device, it is desired that a flow of a processing solution such as an etching solution is uniform with respect to a whole of a semiconductor substrate disposed inside the processing tank, and that processing of the semiconductor substrate using the processing solution is uniform.

### DESCRIPTION OF THE DRAWINGS

FIG. 1 is a front view, shown in partial cross-section, of a substrate processing device of a first embodiment.

FIG. 2 is a drawing showing a first processing solution flow in the substrate processing device shown in FIG. 1.

FIG. 3 is a drawing showing a second processing solution flow in the substrate processing device shown in FIG. 1.

FIG. 4 is a drawing showing a result of a numerical analysis of the flow of the processing solution in the substrate processing device shown in FIG. 1.

FIG. 5 is a drawing showing a flow speed distribution of the processing solution in the substrate processing device shown in FIG. 1.

FIG. 6 is a drawing showing a concentration distribution of silica, which is a reaction product, in the substrate processing device shown in FIG. 1.

FIG. 7 is a drawing showing a result of a numerical analysis of the flow of the processing solution in a substrate processing device of a comparative example.

FIG. 8 is a drawing showing a flow speed distribution of the processing solution in the substrate processing device of the comparative example.

FIG. 9 is a drawing showing a concentration distribution of silica, which is a reaction product, in the substrate processing device of the comparative example.

FIG. 10 is a drawing showing the concentration distribution of silica, which is a reaction product, when a disposition of a substrate in the substrate processing device shown in FIG. 1 is rotated by 90 degrees.

FIG. 11 is a front view, shown in partial cross-section, of a substrate processing device of a second embodiment.

FIG. 12 is a drawing showing a result of a numerical analysis of the flow of the processing solution in the substrate processing device shown in FIG. 11.

FIG. 13 is a drawing showing a flow speed distribution of the processing solution in the substrate processing device shown in FIG. 11.

FIG. 14 is a drawing showing a concentration distribution of silica, which is a reaction product, in the substrate processing device shown in FIG. 11.

FIG. 15 is a front view, shown in partial cross-section, of a substrate processing device of a third embodiment.

FIG. 16 is a drawing showing a result of a numerical analysis of the flow of the processing solution in the substrate processing device shown in FIG. 15.

FIG. 17 is a drawing showing a flow speed distribution of the processing solution in the substrate processing device shown in FIG. 15.

FIG. 18 is a drawing showing a concentration distribution of silica, which is a reaction product, in the substrate processing device shown in FIG. 15.

### DETAILED DESCRIPTION

In general, according to one embodiment, a substrate processing device includes a processing tank including a first region, a second region, and a third region, in which a plurality of substrates are housed in the first region and arranged in a first direction with their faces oriented in an approximately horizontal direction such that a processing of the substrates using a processing solution is carried out, the second region is provided in a vicinity of the first region, and the third region is provided such that the processing solution can move between the first region and the second region; a moving body disposed in the second region of the processing tank and configured to move such that a flow of the processing solution occurs; and a movement mechanism configured to move the moving body.

Hereafter, a substrate processing device of embodiments will be described, referring the drawings. In the embodiments, identical reference signs are allotted to substantially identical components, and a description thereof may be partially omitted. The drawings are schematic, and relationships between thicknesses and planar dimensions, ratios of thicknesses of each portion, and the like, may differ from actual relationships and ratios.

### First Embodiment

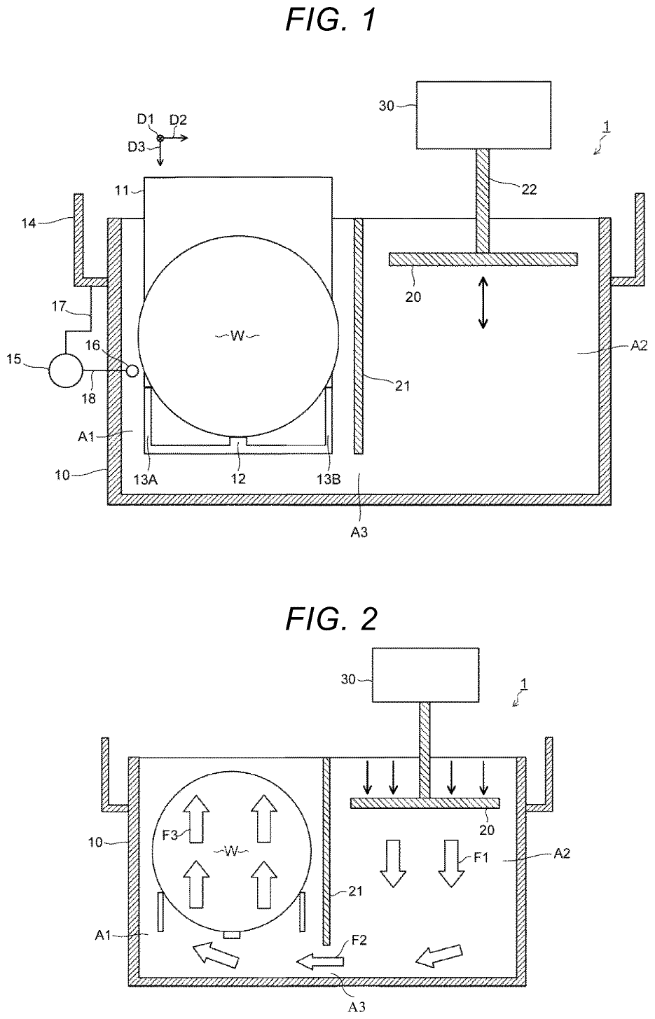

FIG. 1 is a front view, shown in partial cross-section, of a substrate processing device of a first embodiment. A substrate processing device 1 shown in FIG. 1 is a batch-type processing device in which one or more substrates W are each processed using a processing solution, and includes a processing tank 10 to store a processing solution, a moving body 20, which is disposed to be positioned in the processing solution stored in the processing tank 10 and moves such that a flow of the processing solution occurs, and a movement mechanism 30 that causes the moving body 20 to move. A specific configuration of each portion will be described in detail hereafter.

Together with storing the processing solution, the processing tank 10 houses one or more substrates W to be processed using the processing solution arranged in a predetermined direction. The processing tank 10 includes a first region A1 configured to house one or more substrates W, a second region A2 provided in a vicinity of the first region A1, and a third region A3 provided such that the processing solution can move between the first region A1 and the second region A2. A partitioning plate 21 is provided between the first region A1 and the second region A2, and the partitioning plate 21 is provided such that the third region A3 exists between the partitioning plate 21 and a bottom face of the processing tank 10.

The substrates W are arranged in, for example, a first direction (indicated by an arrow D1 in the drawing), with a face (a processing face of the substrate W, on which a device is to be formed, or a face on a back side thereof) of the substrates W oriented in an approximately horizontal direction. The processing solution is selected in accordance with a processing of the substrate W. When carrying out an etching process on a semiconductor substrate applied as the substrate W, an etching solution is used. Various kinds of publicly known etching solution are stored in the processing tank 10 as an etching solution. For example, when etching a silicon nitride film provided on a semiconductor substrate, a phosphoric acid aqueous solution heated to around 150° C. is used.

An aqueous solution of a general inorganic phosphoric acid (orthophosphoric acid) expressed as H₃PO₄ is used as a phosphoric acid aqueous solution acting as a silicon nitride film etching solution. H₄P₂O₇ (pyrophosphoric acid) or the like may be used instead of H₃PO₄, or in addition to H₃PO₄. In order to raise a silicon nitride etching rate, the phosphoric acid aqueous solution may include an additive or the like. For example, a phosphate such as an alkali metal salt of phosphoric acid, organic phosphoric acid, or the like, may be added. Herein, a description will mainly be based on a case in which the substrate processing device 1 is applied to a wet etching device, but not being limited to this, the substrate processing device 1 may also be a substrate cleaning device or the like.

The multiple of substrates W are housed in the first region A1 of the processing tank 10 and arranged in a predetermined direction (for example, the first direction D1), supported by an lifter 11 in an approximately vertical direction, and a predetermined process, such as an etching process, is carried out using the processing solution stored in the processing tank 10. The lifter 11 can be raised and lowered between a processing position (a processing region in the first region A1), in which the substrate W is immersed in the processing solution stored in the processing tank 10, and a standby position above the processing tank 10 using a lifting unit omitted from the drawing. When the lifter 11 is lowered to the processing position, the multiple of substrates W are immersed in the processing solution in a state supported by the lifter 11, and a predetermined process such as an etching process is carried out. The lifter 11 has a central supporting member 12, provided such that the multiple of substrates W can be supported at predetermined intervals and supporting lower edge central portions of the multiple of substrates W, and a pair of side portion supporting members 13A and 13B that support side portions of the multiple of substrates W.

The processing tank 10 includes a circulation system, which causes the processing solution to circulate and has an overflow part 14, a circulation pump 15, a processing solution nozzle 16 that causes the processing solution to be discharged, first piping 17 that connects the overflow part 14 and the circulation pump 15, and second piping 18 that connects the circulation pump 15 and the processing solution nozzle 16. Although omitted from the drawing, a processing solution supply part that supplies the processing solution, a processing solution temperature adjusting art that adjusts a temperature of the processing solution as appropriate, and the like, may also be provided in the processing tank 10. A filter for removing a solid reaction product or the like in the processing solution may also be provided in the circulation system. The overflow part 14 is provided in an upper edge portion of the processing tank 10, and recovers processing solution that overflows from the upper edge of the processing tank 10 due to circulation of the processing solution. The processing solution recovered in the overflow part 14 is fed to the circulation pump 15 via the first piping 17. The processing solution discharged from the circulation pump 15 is fed to the processing solution nozzle 16 via the second piping 18. The processing solution is circulated by being discharged from the processing solution nozzle 16 into the processing tank 10.

The processing tank 10 includes the first region A1 in which the multiple of substrates W supported by the lifter 11 are processed, the second region A2, which neighbors the first region A1 in a second direction D2 that intersects the first direction D1 in a horizontal direction, and the third region A3 which is provided in a space between the bottom face of the processing tank 10 and the partitioning plate 21 extending in a third direction D3 that intersects the first direction D1 in a vertical direction, such that the processing solution can move between the first region A1 and the second region A2. The processing solution is stored in both the first region A1 and the second region A2. The third region A3, which connects the first region A1 and the second region A2, is, of course, also filled with the processing solution, and the processing solution can be caused to circulate.

The moving body 20, which is of a plate form, is disposed in the first direction D1 and the second direction D2 to be positioned in the processing solution in the second region A2. The moving body 20 is connected to the movement mechanism 30 via a drive shaft 22. The movement mechanism 30 causes the moving body 20 disposed in the processing solution to move in an up-down direction (the third direction D3), and causes a flow of the processing solution to occur by a movement of the moving body 20. The moving body 20 is configured of, for example, a plate-form body, and extends in the first direction D1 to correspond to the array of the multiple of substrates W. By causing this kind of plate-form moving body 20 to move repeatedly in the up-down direction (the third direction D3) in the processing solution, a flow occurs in the processing solution in accordance with the movement of the moving body 20.

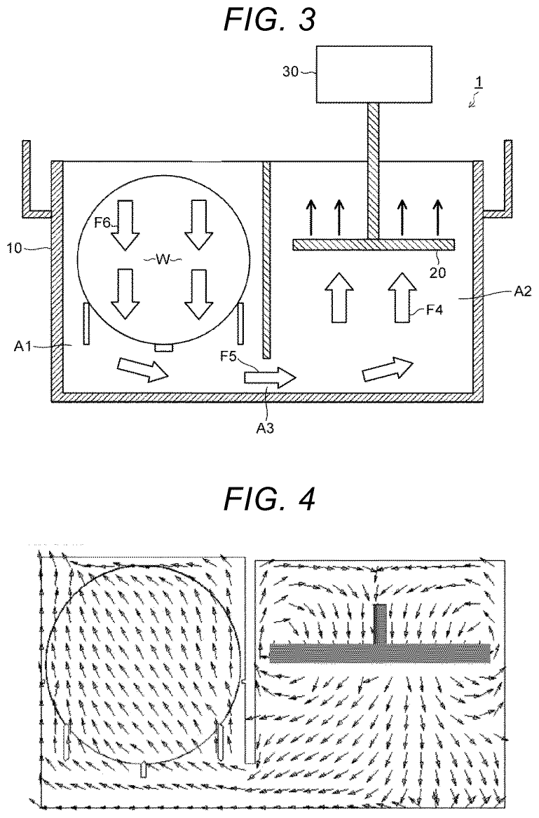

A flow of the processing solution in the substrate processing device 1 of the first embodiment will be described, referring to FIGS. 2 and 3. FIG. 2 is a drawing showing a first processing solution flow accompanying a movement in a downward direction of the moving body 20 in the substrate processing device 1 shown in FIG. 1, and FIG. 3 is a drawing showing a second processing solution flow accompanying a movement in an upward direction of the moving body 20 in the substrate processing device 1 shown in FIG. 1. When the moving body 20 is caused to move in the downward direction (descend), a downward flow F1 of the processing solution occurs in the second region A2 in accompaniment to the movement of the moving body 20, as shown in FIG. 2. Continuing from the flow F1 of the processing solution, a flow F2 of the processing solution occurs in the third region A3, and an upward flow F3 of the processing solution occurs in the first region A1 based on the flow F2. Continuing from the state shown in FIG. 2, when the moving body 20 moves in the upward direction (rises), an upward flow F4 of the processing solution occurs in the second region A2 in accompaniment to the movement of the moving body 20, as shown in FIG. 3. Continuing from the flow F4 of the processing solution, a flow F5 of the processing solution occurs in the third region A3, and a downward flow F6 of the processing solution occurs in the first region A1 based on the flow F5.

By causing the moving body 20 disposed in the processing solution of the second region A2 to move in the up-down direction in this way, the upward flow F3 and the downward flow F6 of the processing solution in the first region A1, in which the multiple of substrates W are disposed, can be caused to occur sequentially. FIG. 4 is a drawing showing a result of a numerical analysis of the flow of the processing solution in the substrate processing device 1 shown in FIG. 1. As shown in FIG. 4, it can be seen that a flow of processing solution occurs in the same direction with respect to a large area of a face of the substrate W. By causing this kind of processing solution flow to occur with respect to a face of the substrate W, a processing of a whole face of the substrate W using the processing solution can be carried out more uniformly and more efficiently.

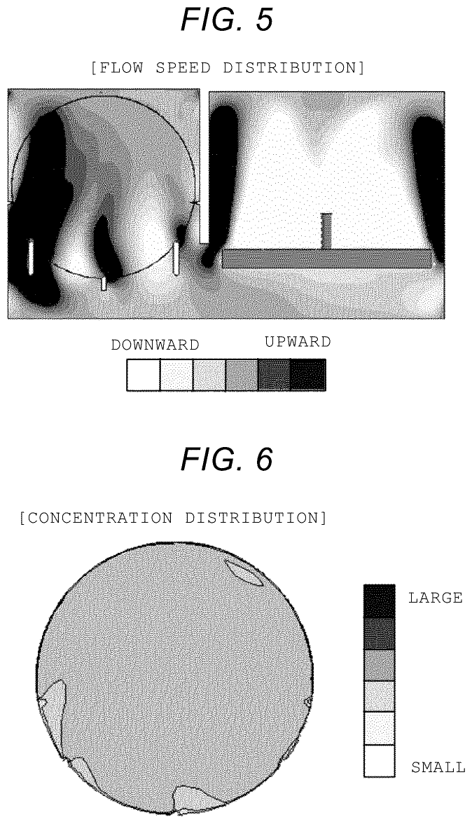

FIG. 5 shows a flow speed distribution of the processing solution when using the substrate processing device 1 shown in FIG. 1. FIG. 6 shows a concentration distribution of silica, which is a reaction product, when using the substrate processing device 1 shown in FIG. 1. FIGS. 5 and 6 show the flow speed distribution of the processing solution and the concentration distribution of silica, which is a reaction product, when using phosphoric acid as the processing solution. As shown in FIG. 5, it can be seen that when using the substrate processing device 1 of the embodiment, variation in the processing solution flow speed is small, and a rate at which portions in which the flow speed is partially high or low occur is small. Furthermore, when using the substrate processing device 1 of the embodiment, variation in the concentration distribution of silica, which is a reaction product, is also small, as shown in FIG. 6. Because of this, it can be seen that, according to the substrate processing device 1 of the embodiment, a processing of a whole face of the substrate W using the processing solution can be carried out more uniformly and more efficiently.

A processing solution flow of an existing substrate processing device, which is such that a processing solution injection nozzle is disposed in a lower portion of a processing tank and a processing solution flow is caused to occur by processing solution injected from the injection nozzle, will be considered as a comparison with the substrate processing device 1 of the heretofore described embodiment. FIG. 7 is a drawing showing a result of a numerical analysis of the flow of the processing solution in the substrate processing device used as a comparative example. When the processing solution is injected from the injection nozzle disposed in the lower portion of the processing tank, and a processing solution flow is caused to occur by the injected processing solution, it is seen that in addition to an upward flow, which is a main processing solution flow, a downward flow opposing the upward flow occurs. That is, an upward flow region in which a flow speed is high occurs in a center, and a flow speed in a periphery thereof is low, together with which a downward flow opposing the upward flow occurs. As a region in which the flow speed is high occurs in the center, a downward flow is easily formed in a periphery thereof, because of which an upward flow and a downward flow are opposed in the peripheral region. Because of this, the existing substrate processing device is such that variation is liable to occur in the processing solution flow speed with respect to a whole face of the substrate W. This is a factor in causing a decrease in uniformity of a processing of a whole face of the substrate W using the processing solution.

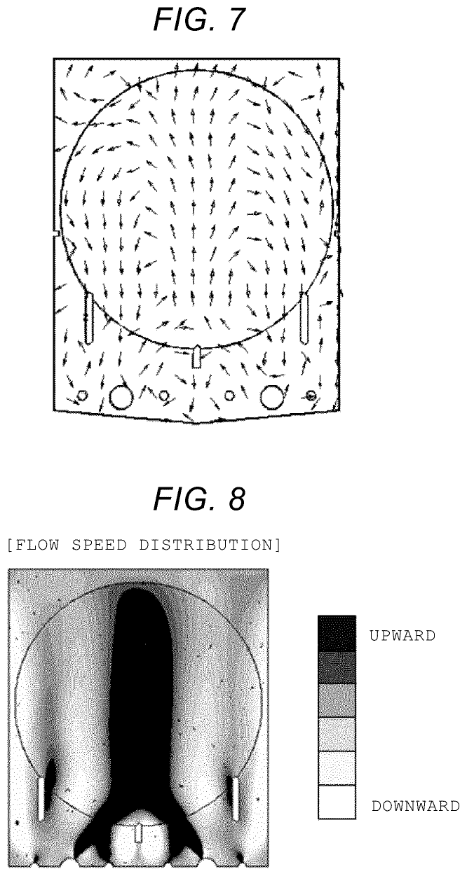

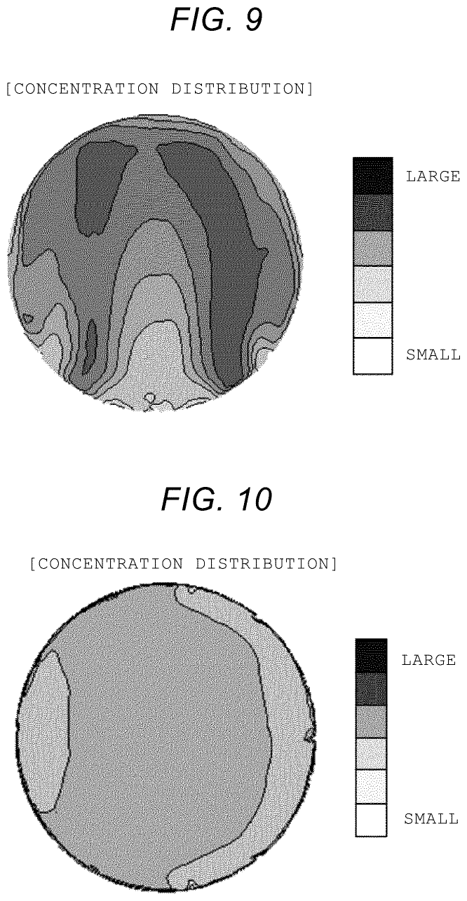

FIG. 8 shows a flow speed distribution of the processing solution when using the substrate processing device shown in FIG. 7. FIG. 9 shows a concentration distribution of silica, which is a reaction product, when using the substrate processing device shown in FIG. 7. As shown in FIG. 8, it can be seen that using the substrate processing device of the comparative example, variation in the processing solution flow speed is large, and portions in which the flow speed is partially high or low are liable to occur. Furthermore, when using the substrate processing device of the comparative example, variation in the concentration distribution of silica, which is a reaction product, is also large, as shown in FIG. 9. Because of this, the substrate processing device of the comparative example is such that variation in processing solution flow speed with respect to a whole face of the substrate W is large, and uniformity of processing the substrate using the processing solution is low.

In the substrate processing device 1 shown in FIG. 1, the multiple of substrates W are housed in the first region A1 and arranged in the first direction D1, but the direction in which the multiple of substrates W are arrayed may also be the second direction D2. That is, the multiple of substrates W may also be disposed in a state rotated by 90 degrees in the substrate processing device 1 shown in FIG. 1. As shown in FIG. 4, the processing solution flows upward from below, meaning that regardless of whether the direction in which the multiple of substrates W are arrayed is the first direction D1 or the second direction D2, variation in the processing solution flow speed and variation in the concentration distribution of silica, which is a reaction product, can be reduced. FIG. 10 shows the concentration distribution of which is a reaction product, when the disposition of the substrate W in the substrate processing device 1 shown in FIG. 1 is rotated by 90 degrees. Even when the disposition of the substrate W is rotated by 90 degrees, variation in the concentration distribution of silica can be reduced. This is clear from a comparison with FIG. 9.

### Second Embodiment

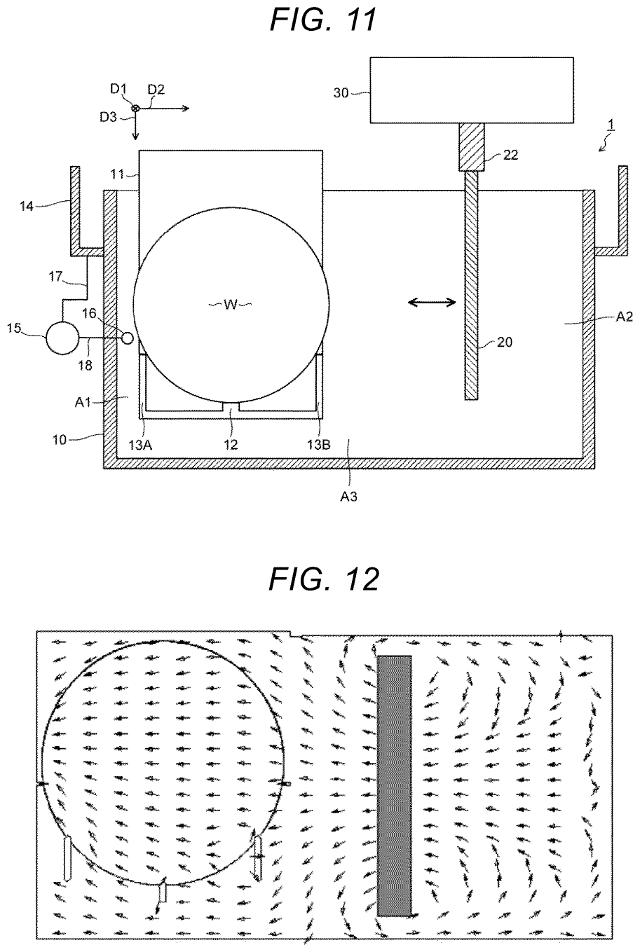

FIG. 11 is a front view, shown in partial cross-section, of a substrate processing device of a second embodiment. The substrate processing device 1 shown in FIG. 11, in the same way as the substrate processing device 1 of the first embodiment, is a batch-type processing device in which the multiple of substrates W are processed at one time using a processing solution, and includes the processing tank 10 in which the processing solution is stored, the moving body 20, which is disposed to be positioned in the processing solution stored in the processing tank 10 and moves such that a flow of the processing solution occurs, and the movement mechanism 30 that causes the moving body 20 to move. Hereafter, a description will mainly focus on differences between the substrate processing device 1 of the second embodiment shown in FIG. 11 and the substrate processing device 1 of the first embodiment shown in FIG. 1.

In the processing tank 10 of the substrate processing device 1 shown in FIG. 11, the second region A2 is provided in a vicinity of the first region A1 in which the multiple of substrates W are housed, along with the first region A1 in the second direction D2. This point is the same as in the substrate processing device 1 shown in FIG. 1. However, the partitioning plate 21 is not provided between the first region A1 and the second region A2, and between the first region A1 and the second region A2 is the third region A3. The multiple of substrates W are arranged in the first direction D1, with faces thereof oriented in an approximately horizontal direction.

The plate-form moving body 20 is disposed in the first direction D1 and the third direction D3 to be positioned in the processing solution in the second region A2. A face of the plate-form moving body 20 extends in the first direction D1 to oppose the array of the multiple of substrates W. The moving body 20 is connected to the movement mechanism 30 via the drive shaft 22. The movement mechanism 30 causes the moving body 20 disposed in the processing solution to move repeatedly in the second direction D2 (a left-right direction in the drawing), and causes a flow of the processing solution to occur by a movement of the moving body 20. By causing this kind of plate-form moving body 20 to move repeatedly in the left-right direction (the second direction D2) in the processing solution, a flow occurs in the processing solution in accordance with the movement of the moving body 20.

By causing the moving body 20 disposed in the processing solution of the second region A2 to repeatedly move in the left-right direction in this way, a leftward flow and a rightward flow of the processing solution in the first region A1, in which the multiple of substrates W are disposed, can be caused to occur sequentially. FIG. 12 is a drawing showing a result of a numerical analysis of the flow of the processing solution in the substrate processing device 1 shown in FIG. 11. As shown in FIG. 12, it can be seen that a flow of processing solution occurs in the same direction with respect to a large area of a face of the substrate W. By causing this kind of processing solution flow to occur with respect to a face of the substrate W, a processing of a whole face of the substrate W using the processing solution can be carried out more uniformly and more efficiently.

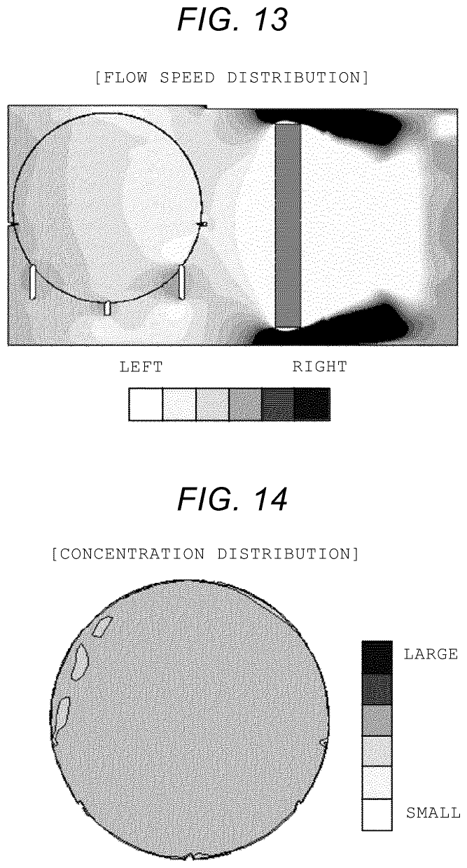

FIG. 13 shows a flow speed distribution of the processing solution when using the substrate processing device 1 shown in FIG. 11. FIG. 14 shows a concentration distribution of silica, which is a reaction product, when using the substrate processing device 1 shown in FIG. 11. FIGS. 13 and 14 show the flow speed distribution of the processing solution and the concentration distribution of silica, which is a reaction product, when using phosphoric acid as the processing solution. As shown in FIG. 13, it can be seen that when using the substrate processing device 1 of the embodiment, variation in the processing solution flow speed is small, and a rate at which portions in which the flow speed is partially high or low occur is small. Furthermore, when using the substrate processing device 1 of the embodiment, variation in the concentration distribution of silica, which is a reaction product, is also small, as shown in FIG. 14. Because of this, it can be seen that, according to the substrate processing device 1 of the embodiment, a processing of a whole face of the substrate W using the processing solution can be carried out more uniformly and more efficiently.

### Third Embodiment

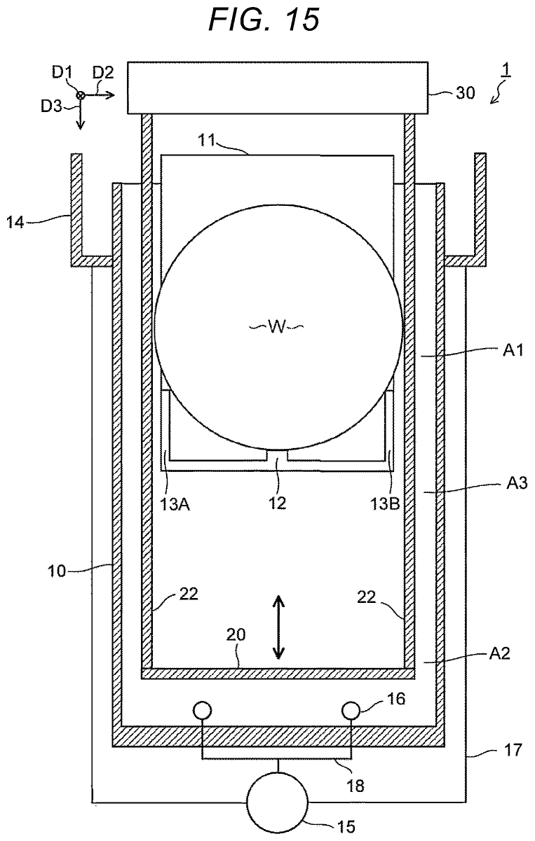

FIG. 15 is a front view, shown in partial cross-section, of a substrate processing device of a third embodiment. The substrate processing device 1 shown in FIG. 15, in the same way as the substrate processing device 1 of the first embodiment, is a batch-type processing device in which the multiple of substrates W are processed at one time using a processing solution, and includes the processing tank 10 in which the processing solution is stored, the moving body 20, which is disposed to be positioned in the processing solution stored in the processing tank 10 and moves such that a flow of the processing solution occurs, and the movement mechanism 30 that causes the moving body 20 to move. Hereafter, a description will mainly focus on differences between the substrate processing device 1 of the third embodiment shown in FIG. 15 and the substrate processing device 1 of the first embodiment shown in FIG. 1. A description of portions of the substrate processing device 1 shown in FIG. 15 identical to those of the substrate processing device 1 shown in FIG. 1 will be partially omitted.

The processing tank 10 of the substrate processing device 1 shown in FIG. 15 includes the first region A1 in which the processing solution is stored, and in which the multiple of substrates W to be processed using the processing solution are arranged in the first direction D1, the second region A2, which is provided along with the first region A1 in the third direction D3 (the up-down direction), and the third region A3, which is provided such that the processing solution can move between the first region A1 and the second region A2. The second region A2 is disposed in a vicinity of a lower side of the first region A1. No partitioning plate or the like is provided between the first region A1 and the second region A2, and between the first region A1 and the second region A2 is the third region A3.

The plate-form moving body 20 is disposed on the lower side of the first region A1 in the first direction D1 and the second direction D2 to be positioned in the processing solution in the second region A2. The moving body 20 is connected to the movement mechanism 30 via the drive shaft 22, which is provided in four corners of the plate-form body. The moving body 20 may have a plate-form drive body provided on one side of the plate-form body instead of the drive shaft 22 provided in the four corners of the plate-form body. The movement mechanism 30 causes the moving body 20 disposed in the processing solution to move in the up-down direction (the third direction D3), and causes a flow of the processing solution to occur by a movement of the moving body 20. The moving body 20 is configured with, for example, a plate-form body, and extends in the first direction D1 such that a face thereof opposes the array of the multiple of substrates W. By causing this kind of plate-form moving body 20 to move repeatedly in the up-down direction (the third direction D3) in the processing solution, a flow occurs in the processing solution in accordance with the movement of the moving body 20.

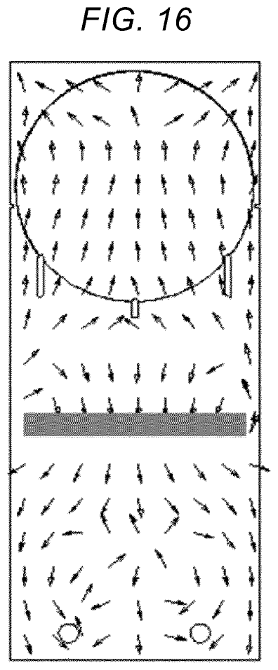

By causing the moving body 20 disposed in the processing solution of the second region A2 to repeatedly move in the up-down direction in this way, an upward flow and a downward flow of the processing solution in the first region A1, in which the multiple of substrates W are disposed, can be caused to occur sequentially. FIG. 16 is a drawing showing a result of a numerical analysis of the flow of the processing solution in the substrate processing device 1 shown in FIG. 15. As shown in FIG. 16, it can be seen that a flow of processing solution occurs in the same direction with respect to a large area of a face of the substrate W. By causing this kind of processing solution flow to occur with respect to a face of the substrate W, a processing of a whole face of the substrate W using the processing solution can be carried out more uniformly and more efficiently.

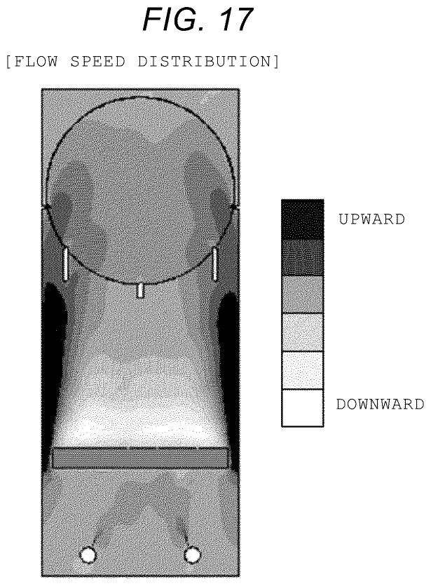

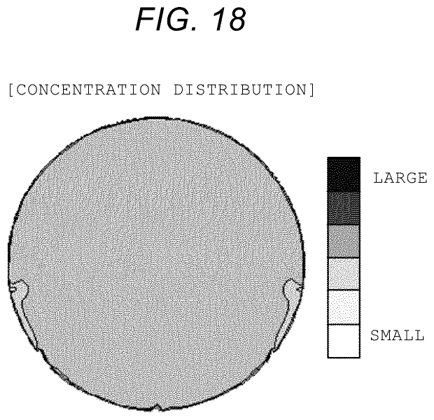

FIG. 17 shows a flow speed distribution of the processing solution when using the substrate processing device 1 shown in FIG. 15. FIG. 18 shows a concentration distribution of silica, which is a reaction product, when using the substrate processing device 1 shown in FIG. 15. FIGS. 17 and 18 show the flow speed distribution of the processing solution and the concentration distribution of silica, which is a reaction product, when using phosphoric acid as the processing solution. As shown in FIG. 17, it can be seen that when using the substrate processing device 1 of the embodiment, variation in the processing solution flow speed is small, and a rate at which portions in which the flow speed is partially high or low occur is small. Furthermore, when using the substrate processing device 1 of the embodiment, variation in the concentration distribution of silica, which is a reaction product, is also small, as shown in FIG. 18. Because of this, it can be seen that, according to the substrate processing device 1 of the embodiment, a processing of a whole face of the substrate W using the processing solution can be carried out more uniformly and more efficiently.

In the substrate processing device 1 shown in FIG. 15, the multiple of substrates W are housed in the first region A1 and arranged in the first direction D1, but the direction in which the multiple of substrates W are arrayed may also be the second direction D2. That is, the multiple of substrates W may also be disposed in a state rotated by 90 degrees in the substrate processing device 1 shown in FIG. 15. In this way, the substrate processing device 1 shown in FIG. 15 is such that the processing solution flows upward from below and flows downward from above, meaning that regardless of whether the direction in which the multiple of substrates W are arrayed is the first direction D1 or the second direction D2, variation in the processing solution flow speed and variation in the concentration distribution of silica, which is a reaction product, can be reduced.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing device, comprising:
a processing tank including a first region, a second region, and a third region, in which a plurality of substrates are housed in the first region and arranged in a first direction with their faces oriented in an approximately horizontal direction such that a processing of the substrates using a processing solution is carried out, the second region is provided in a vicinity of the first region, and the third region is provided such that the processing solution can move between the first region and the second region;
a moving body disposed in the second region of the processing tank and configured to move such that a flow of the processing solution occurs; and
a movement mechanism configured to move the moving body.

2. The substrate processing device according to claim 1, wherein the moving body includes a plate-form body disposed in the processing solution.

3. The substrate processing device according to claim 2, wherein the plate-form body extends in the first direction to correspond to an arrangement of the plurality of substrates.

4. The substrate processing device according to claim 1, wherein the second region is provided to neighbor the first region in the first direction, or in a second direction that intersects the first direction in a horizontal direction,
a partitioning plate is provided between the first region and the second region such that the third region is positioned between the partitioning plate and a bottom face of the processing tank,
the moving body is disposed in the first direction, and
the movement mechanism is configured to move the moving body in a third direction that intersects the first direction in a vertical direction.

5. The substrate processing device according to claim 1, wherein the second region is provided along with the first region in a second direction that intersects the first direction in a horizontal direction, sandwiching the third region between the first region and the second region,
the moving body is disposed in the first direction, and
the movement mechanism is configured to move the moving body in the second direction.

6. The substrate processing device according to claim 5, wherein the moving body is a plate-form body further disposed in a third direction that intersects the first direction in a vertical direction, and a face thereof is disposed to oppose the plurality of substrates.

7. The substrate processing device according to claim 5, wherein no partitioning plate is provided between the first region and the second region.

8. The substrate processing device according to claim 1, wherein the second region is provided along with the first region in a third direction that intersects the first direction in a vertical direction, sandwiching the third region between the first region and the second region,
the moving body is disposed in the first direction, and
the movement mechanism is configured to move the moving body in the third direction.

9. The substrate processing device according to claim 8, wherein the moving body is a plate-form body further disposed in a second direction that intersects the first direction in a horizontal direction, and a face thereof is disposed to oppose the plurality of substrates.

10. The substrate processing device according to claim 8, wherein no partitioning plate is provided between the first region and the second region.

11. The substrate processing device according to claim 1, wherein the movement mechanism causes the moving body to move repeatedly in a predetermined direction.

12. The substrate processing device according to claim 1, wherein the movement mechanism is provided in an exterior of the processing tank, and is coupled to the moving body through a drive shaft.

13. The substrate processing device according to claim 1, further comprising:
an overflow part configured to recover the processing solution overflowing from the processing tank;
a circulation piping configured to return the processing solution recovered in the overflow part to the processing tank; and
a circulation pump provided in the circulation piping.

14. The substrate processing device according to claim 1, further comprising a lifter configured to support the substrates, and rise and descend between the first region of the processing tank and a standby position of the substrates above the processing tank.

15. A substrate processing method, comprising:
disposing, in a first region of a processing tank in which a processing solution is stored, a plurality of substrates arranged in a direction with their faces oriented in an approximately horizontal direction, and disposing a moving body in a second region of the processing tank neighboring the first region in a horizontal direction via a partitioning plate, such that the second region communicates with the first region via a third region positioned between the partitioning plate and a bottom face of the processing tank, and
causing the moving body to move in an approximately vertical direction in the second region.

16. The substrate processing method according to claim 15, wherein the moving body is caused to move repeatedly in the approximately vertical direction in the second region.

17. The substrate processing method according to claim 15, wherein the processing solution includes an etching solution, and films provided on the substrates are etched using the etching solution.

18. A substrate processing method, comprising:
disposing, in a first region of a processing tank in which a processing solution is stored, a plurality of substrates arranged in a first direction with their faces oriented in an approximately horizontal direction, and disposing a moving body in a second region of the processing tank positioned in a vicinity of the first region in an intersecting direction that intersects the first direction, and
causing the moving body to move in the intersecting direction in the second region.

19. The substrate processing method according to claim 18, wherein the moving body is caused to move repeatedly in the intersecting direction in the second region.

20. The substrate processing method according to claim 18, wherein the processing solution includes an etching solution, and films provided on the substrates are etched using the etching solution.
